(19) United States
(12) Patent Application Publication
(10) Pub. No.: US 2010/0289499 A1
(43) Pub. Date: Nov. 18, 2010

(54) MONITORING DEVICE FOR MONITORING A TERMINAL OF A TERMINAL COMPONENT

(76) Inventors: Marcus Bremmer, Benningen Am Neckar (DE); Arnold Winter, Filderstadt (DE); Dragan Mikulec, Stuttgart (DE)

Correspondence Address: KENYON & KENYON LLP, ONE BROADWAY, NEW YORK, NY, 10004, US

(21) Appl. No.: 12/733,211

(22) PCT Filed: Jul. 31, 2008
(86) PCT No.: PCT/EP2008/060081

§ 371 Date: May 20, 2010

(30) Foreign Application Priority Data
Aug. 17, 2007 (DE) 10 2007 038 990.8

(51) Int. Cl. G01R 31/02

(52) U.S. Cl. 324/503

(57) ABSTRACT

A monitoring device for monitoring a terminal of a terminal component in a power supply system is described, the terminal component being connectable to the power supply system and to a monitoring system via an electrical connection element, and the monitoring device comprising a voltage measuring device for detecting a voltage value of a voltage between a first terminal and a second terminal of the electrical connection element, the first terminal and the second terminal being connectable to the monitoring system, and an evaluation device for evaluating the voltage value, the evaluation device being designed to generate an indicating signal, which indicates a faulty connection to the power supply system if the voltage value differs from a predetermined voltage value.

### FIELD OF THE INVENTION

The present invention relates to monitoring of a terminal of a terminal component, e.g., an electric consumer or a housing, having a power supply system, in particular in a motor vehicle.

### BACKGROUND INFORMATION

In modern vehicles, e.g., hybrid vehicles or fuel cell vehicles, in addition to a 14-V vehicle electric system, a low-voltage system is installed to supply the consumers provided in the vehicle. The voltages occurring in such a low-voltage system are approximately 200 V to 1000 V, which are thus so high that hazardous shock currents may flow when active parts under such a low voltage are touched. For such a low-voltage system, safety measures must therefore be taken to protect against direct and indirect contact with active parts under a low voltage, such as those described in the DIN VDE 0100 standard, for example.

One of the safety measures is for all plug connections to be plugged in and possibly locked in place when the low-voltage system is connected and for all housing covers to be correctly mounted. To do so, the plug connectors are provided with two additional contacts and are monitored and wired with any housing cover contacts that might be present via a monitoring line. This monitoring line is often referred to as a pilot line or an interlog line.

If all the plugs which are monitored with the pilot line are plugged correctly, this is recognized by a central monitoring unit, which enables the low-voltage system for activation. In addition, the housing cover is monitored for its presence and correct assembly, so that low-voltage-carrying parts in the interior of the housing cannot be touched.

One disadvantage of pilot line monitoring is that only an interruption in the pilot line is detected but the location of the interruption is not detected at the same time. Thus, for example, a central monitoring system may detect the existence of an interruption in the pilot line and thus a fault. However, the location of the fault cannot be determined accurately, possibly resulting in complex and expensive troubleshooting in complex systems. Furthermore, if any additional measures are necessary in one of the low-voltage components due to the defect detected, they must be reported by the central monitoring system. This results in a system-related time lag, which may be critical for system security in certain situations.

### SUMMARY OF THE INVENTION

An object of the exemplary embodiments and/or exemplary methods of the present invention is to create a concept for monitoring electrical connections that will allow secure detection of defects and location of defects.

This object is achieved by the features described herein. Advantageous refinements are further characterized and described herein.

The exemplary embodiments and/or exemplary methods of the present invention relates to a monitoring device for monitoring a terminal of a terminal component on a power supply system, the terminal component being connectable to the power supply system and, via an electrical connection element, to a monitoring system. The monitoring device may include a voltage measuring device for detecting a voltage value of a voltage between a first terminal and a second terminal of the electrical connection element, the first terminal and the second terminal being connectable to the monitoring system, and an evaluation unit is designed for evaluating the voltage value, the evaluation unit being designed to generate an indicating signal, which indicates a faulty terminal in the power supply system if the voltage value differs from a predetermined voltage value.

According to one specific embodiment, a resistor element is connectable between the first terminal and the second terminal.

According to another specific embodiment, the evaluation unit is designed to generate an indicating signal if the voltage value differs from the predetermined voltage value.

According to another specific embodiment, the predetermined voltage value is between 0 volts and 1 volt. The predetermined voltage value may be 0 volts.

According to another specific embodiment, the monitoring device is situated in the connection element.

The exemplary embodiments and/or exemplary methods of the present invention also relates to a terminal component, in particular a vehicle battery or a vehicle ignition coil or vehicle control unit or a low-voltage vehicle battery system or a component housing or a component housing cover having the monitoring device according to the present invention, which may be integrated into the terminal component, for example.

The exemplary embodiments and/or exemplary methods of the present invention furthermore relates to a monitoring system for monitoring a terminal of at least one terminal component in a power supply system, the terminal component being connectable to the power supply system and, via an electrical connection element, to a monitoring system. The monitoring system may include the monitoring device according to the present invention and a power generating device, in particular a power source for supplying an electric current of a predetermined amplitude to the first terminal of the connection element to produce a voltage drop between the first terminal and the second terminal.

According to one specific embodiment, the monitoring system also includes another connection element, to which the connection element of the terminal component is connectable, the additional connection element having a low-impedance connection or a resistor element between the first terminal of the additional connection element and the second terminal of the additional connection element, the terminals of the additional connection element being connectable to the terminals of the connection element.

According to another specific embodiment, the monitoring system also includes a central evaluation unit, which is connectable to the evaluation unit of the monitoring device according to the present invention to receive the indicating signal and to output a fault signal indicating the terminal component in the event of a connection fault.

The exemplary embodiments and/or exemplary methods of the present invention also relates to a vehicle power system having the monitoring device according to the present invention and the monitoring system according to the present invention.

Additional exemplary embodiments are explained with reference to the accompanying drawings.

### BRIEF DESCRIPTION OF THE DRAWINGS

FIG. 1 shows a monitoring system having monitoring devices according to one specific embodiment of the present invention connected thereto.

FIG. 2 shows a monitoring system having monitoring devices connected thereto according to another specific embodiment of the present invention.

FIG. 3 shows a monitoring system having monitoring devices connected thereto according to another specific embodiment of the present invention.

FIG. 4 shows a monitoring system having monitoring devices connected thereto according to another specific embodiment of the present invention.

FIG. 5 shows a monitoring system having monitoring devices connected thereto according to another specific embodiment of the present invention.

FIG. 6a and FIG. 6b show a monitoring system having monitoring devices connected thereto according to another specific embodiment of the present invention.

FIG. 7a, FIG. 7b, and FIG. 7c show electrical connections.

FIG. 8a, FIG. 8b, and FIG. 8c show electrical connections.

### DETAILED DESCRIPTION

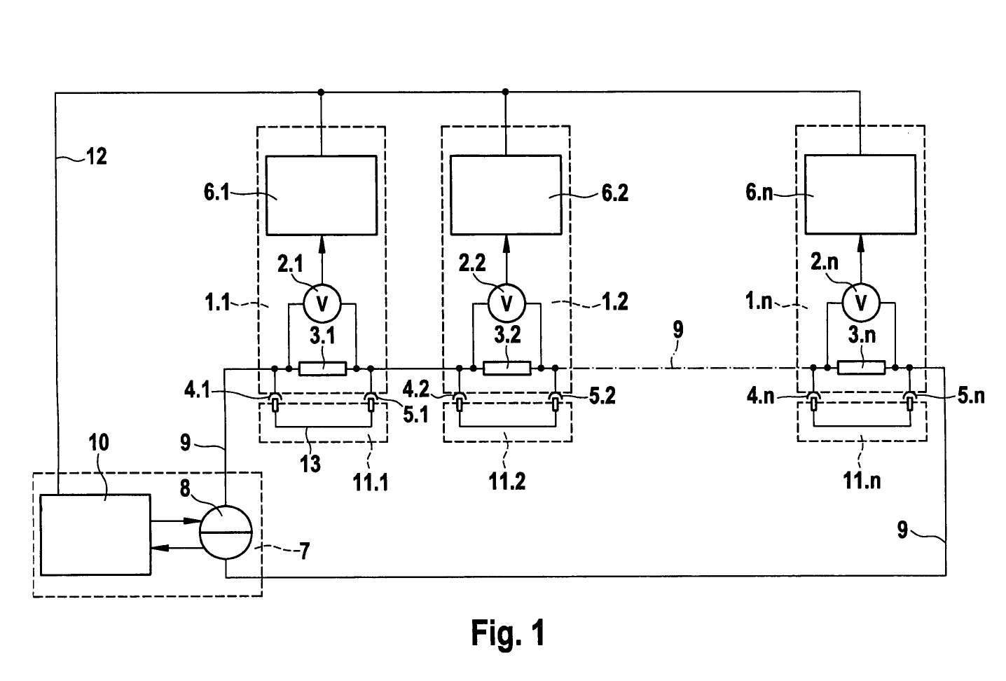

FIG. 1 shows an example of a plurality of monitoring devices 1.1, 1.2, 1.n, each having a voltage measuring device 2.1, 2.2, 2.n, a resistor element 3.1, 3.2, 3.n connected in parallel to voltage measuring device 2.1, 2.2, 2.n, and each having a connection element comprising a first terminal 4.1, 4.2, 4.n and a second terminal 5.1, 5.2, 5.n. Resistor element 3.1, 3.2, 3.n is situated between first terminal 4.1, 4.2, 4.n and second terminal 5.1, 5.2, 5.n. One output of each voltage measuring device 2.1, 2.2, 2.n is connected to an input of an evaluation unit 6.1, 6.2, 6.n.

Monitoring devices 1.1 to 1.n are connected to a monitoring system, which may include a power source unit 7 having a power source 8 and a pilot line 9. Furthermore, power source unit 7 includes a control and evaluation unit 10, which is connected to power source 8.

Another connection element 11.1 to 11.n of the monitoring system, by which a particular monitoring device 1.1 to 1.n is connectable to pilot line 9 and thus to power source 8, is allocated to each connection element of particular monitoring device 1.1 to 1.n.

The monitoring system also includes a connecting line 12, e.g., a bus line to which one output of particular evaluation unit 6 of particular monitoring device 1.1 to 1.n is connected. Connecting line 12 connects evaluation unit 6.1, 6.2 to 6.n to central control and evaluation unit 10.

Reference is made below to monitoring device 1.1 as an example:

As shown in FIG. 1, the particular additional connection element 11.1 of the monitoring system is provided with two plug contacts 4.1, 5.1, which are conductively connected and engage with the corresponding plug contacts of the connection element of monitoring device 1.1 when connected. As shown in FIG. 1, first terminal 4.1 and second terminal 5.1 of the connection element of monitoring device 1.1 are short circuited via additional connection element 11.1 in the event of a faulty plug connection.

If the connections are fault-free, then there is no voltage drop across resistor 3.1 of monitoring device 1.1, for example, so evaluation unit 6.1 of control and evaluation unit 10 may optionally report a fault-free connection. However, in the event of a faulty connection, terminals 4.1 and 4.5 of the connection element of the monitoring device 1.1 are no longer bridged, so that resistor 3.1 is no longer bridged, so there may be a voltage drop there in principle. The power source may therefore be connected to resistor element 3.1 via additional terminals (not shown in FIG. 1) and may drive a current through them, generating a voltage drop across resistor element 3.1 in the event of a faulty connection.

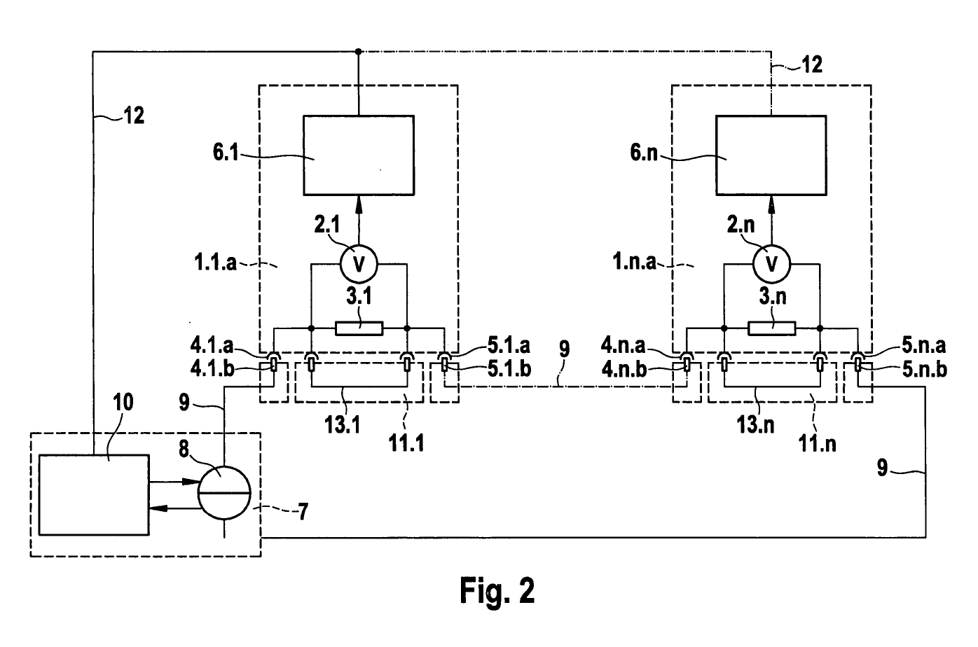

FIG. 2 shows a plurality of monitoring devices 1.1.a, 1.n.a, each having a voltage measuring device 2.1, 2.n, a resistor element 3.1, 3.n and an evaluation unit 6.1, 6.n and being wired as shown in FIG. 1. In contrast with the exemplary embodiment shown in FIG. 1, the additional connection elements of the monitoring system each include a terminal pair having a first terminal 4.1.b, 4.n.b and a second terminal 5.1.b, 5.n.b, which are provided for connecting a particular monitoring device 1.1.a, 1.n.a to pilot line 9, each via a first terminal 4.1.a, 4.n.a and a second terminal 5.1.a, 5.n.a. Furthermore, the additional connection elements of the monitoring system assigned to monitoring devices 1.1.a, 1.n.a include additional terminals 11.1, 11.n, which are connected at a low impedance via a short-circuit bridge 13.1, 13.n.

Reference is made below to monitoring device 1.1 as an example:

Monitoring device 1.1.a includes a connection element, which is provided for connection to the additional connection element of the monitoring system. The connection element includes first terminal 4.1.a, which is connectable to first terminal 4.1.b of the additional connection element, and second terminal 5.1.a, which is connectable to second terminal 5.1.b of the additional connection element. For example, resistor element 3.1 is situated between first terminal 4.1.a and second terminal 5.1.a. In addition, the connection element of monitoring device 1.1.a includes another terminal pair, which is connectable to the terminals of the additional connection element of the monitoring system, bridged by bridge 13.1.

Bridging of resistor element 3.1 is thus implemented with a fault-free connection of the connection element of monitoring device 1.1.a to the additional connection element of the monitoring system, so that the current flows through power source 8 into first terminal 4.1.b of the additional connection element via the bridge and not across resistor element 3.1, so there is no detectable voltage drop across this resistor element. In this case, evaluation unit 6.1 detects that the connection to the monitoring system and thus the connection to the power system is fault-free.

Terminals 4.1.b, 5.1.b may be situated on the low-voltage side with a vehicle electric system voltage of 14 V, for example. The additional terminal pairs, which are connected by bridge 13.1, however, may be situated on the low-voltage side. The additional connection element may thus be designed in several parts, so that in the event of a faulty connection between monitoring device 1.1.a and the power supply system, for example, resistor element 3.1 is no longer bridged, so that if there is a fault-free connection to the monitoring system, a current flowing through it cannot contribute to the voltage drop.

In the event of a faulty connection between monitoring device 1.1.a, 1.n.a and the monitoring system, no current flow develops due to the serial connection of the monitoring devices. Power source 8 in this case may detect that no current is flowing and may generate an indicating signal, indicating a faulty connection of particular monitoring device 1.1.a, 1.n.a to the monitoring system. Since power source 8 is connected to control and evaluation unit 10, control and evaluation unit 10 receives the indicating signal, so that fault detection is also possible in the event of a faulty connection to the monitoring system.

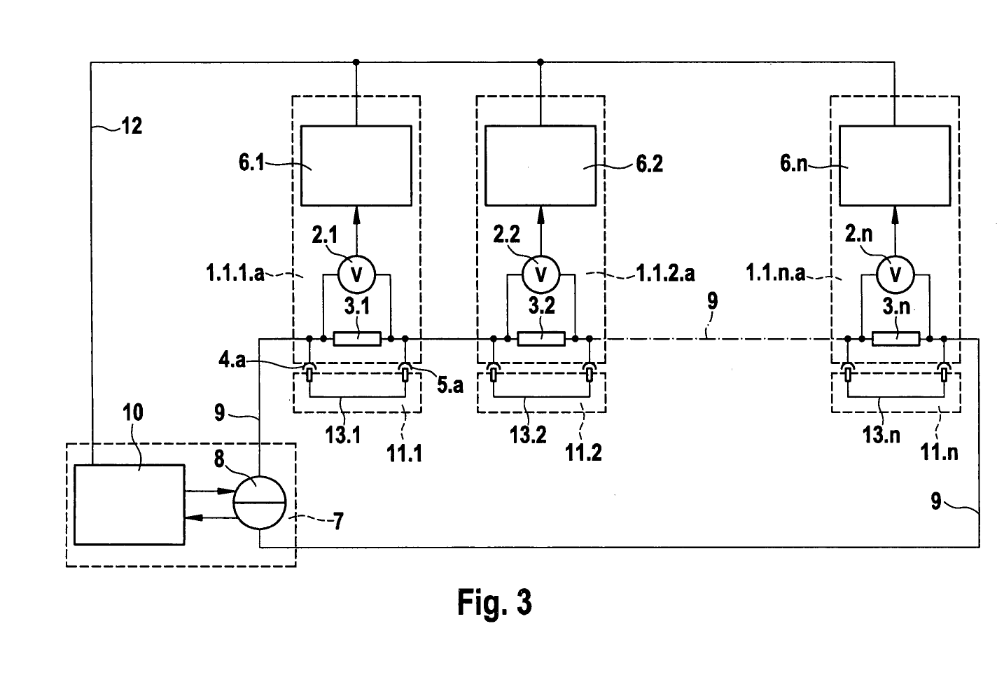

FIG. 3 shows an arrangement of a plurality of monitoring devices 1.1.1.a to 1.1.n.a, each having a voltage measuring device 2.1, 2.2, 2.n, an evaluation unit 6.1, 6.2, 6.n and a resistor element 3.1, 3.2, 3.n. In contrast with the exemplary embodiment shown in FIG. 2, power source 8 is permanently connected to a first terminal of a connection element of particular monitoring device 1.1.1.a, 1.1.n.a, monitoring devices 1.1.1.a, 1.1.n.a being connected in series and together with pilot line 9 forming a serial connection to power source 8.

The additional terminals having bridges 13.1, 13.n are assigned to the low-voltage side, for example, and bridge resistor elements 3.1, 3.n, in the event of a fault-free connection to the low-voltage system, so there is no detectable voltage drop there. In the event of a faulty connection of one monitoring device 1.1.1.a, 1.1.n.a to the power system via terminals 4.a and 5.a, for example, particular resistor element 3.1, 3.n is no longer bridged, so that a current flow through it may develop, contributing to the voltage drop, which particular evaluation unit 6.1, 6.2, 6.n may detect and, in response, to generate an indicating signal, which is sent to control line evaluation unit 10 via bus connection 12.

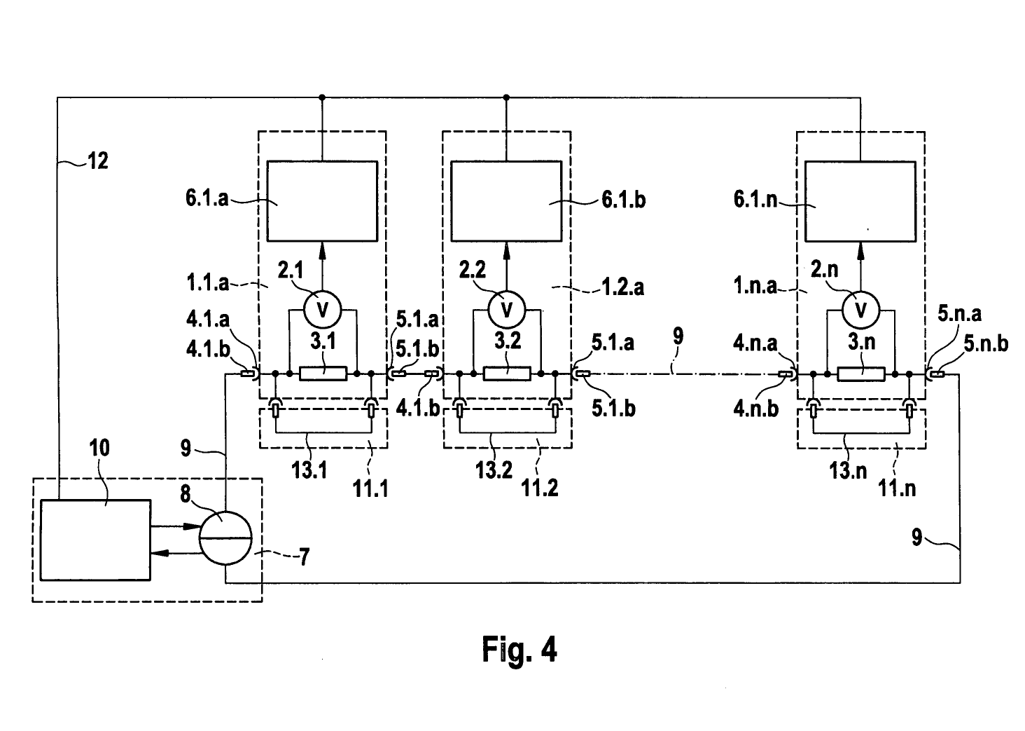

FIG. 4 shows an arrangement of a plurality of monitoring devices 1.1.a, 1.2.a, 1.n.a having evaluation units 6.1.a, 6.1.b, 6.1.n connectable to the monitoring system via connection elements, which are separate from the low-voltage side, in contrast with the exemplary embodiment shown in FIG. 3 and in modification of the exemplary embodiment shown in FIG. 2. Thus, for example, monitoring device 1.1.a shown in FIG. 4 is connected via terminals 4.1.a, 5.1.a of the connection element to corresponding terminals 4.1.b, 5.1.b of the monitoring system. However, terminals 4.1.b, 5.1.b are not always situated within the additional connection element of the monitoring system but instead may be embodied as external components.

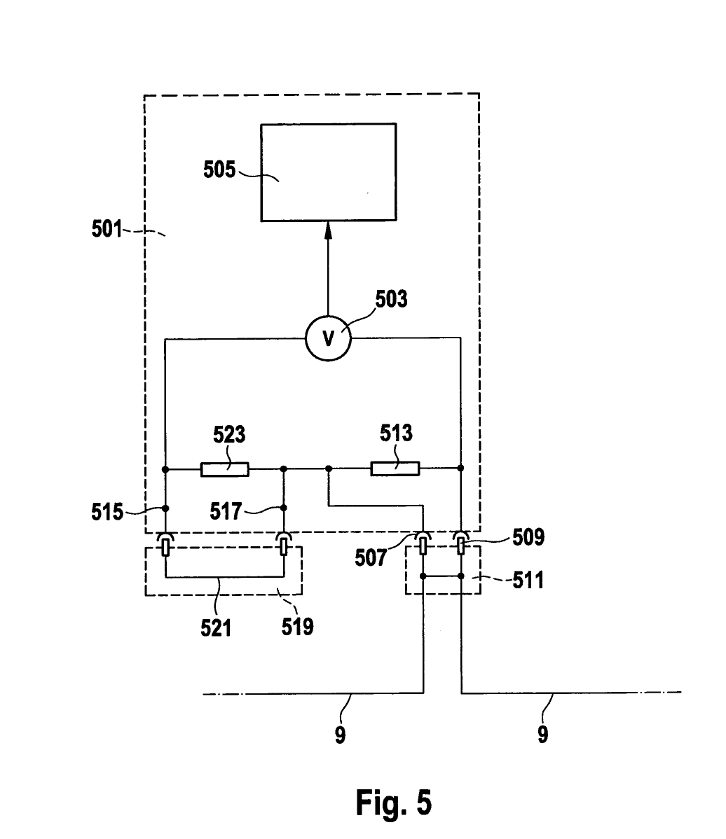

FIG. 5 shows a monitoring device 501 having a voltage measuring device 503 whose output is connected to an input of an evaluation unit 505. The monitoring device is connected to pilot line 9 via a first terminal 507 and a second terminal 509, terminals 507 and 509 being connected with a low impedance and optionally short circuited. Terminals 507 and 509 are also assigned to a connection element of monitoring device 501 and are connectable to another connection element 511 of the monitoring system, which has the above-mentioned short-circuit bridge. A resistor element 513 is situated between first terminal 507 and second terminal 509.

Monitoring device 501 also includes additional terminals 515 and 517, which are connectable to one another by an additional connection element 519 of the monitoring system to pilot line 9, which includes a short-circuit bridge 521. Additional connection element 519 may be assigned to the low-voltage side. Another resistor element 523 is situated between terminals 515 and 517.

Voltage measuring device 503 is provided to measure a voltage between terminals 515 and 509. If there is a faulty connection between monitoring device 501 and the power system, bridge 521 bridges resistor element 523, so there is no voltage drop. If there is a faulty connection to the monitoring system, resistor element 513 is also short-circuited, so the voltage measuring device does not measure a detectable voltage.

However, the short-circuit connection in additional connection element 511 is optional, so that when it is omitted, a current may be fed into first terminal 507, resulting in a voltage drop detectable by voltage measuring device 503, which may have a predetermined amplitude, e.g., 1 V or 2 V, for example, in the event of a faulty connection.

If the connection to the power system is faulty and if the bridge situated in additional connection element 511 is omitted, then resistor element 523 is no longer short-circuited, so the power fed into first terminal 507 results in a second voltage drop having a different voltage amplitude, which is detectable by voltage measuring device 503. If the additional voltage amplitude differs from the predetermined threshold value, e.g., from the voltage amplitude, which drops in the event of a faulty connection of monitoring device 501 to the power system, and if the short-circuit connection to resistor element 513 is eliminated, this difference is detected by evaluation unit 505, so the faulty connection is localizable.

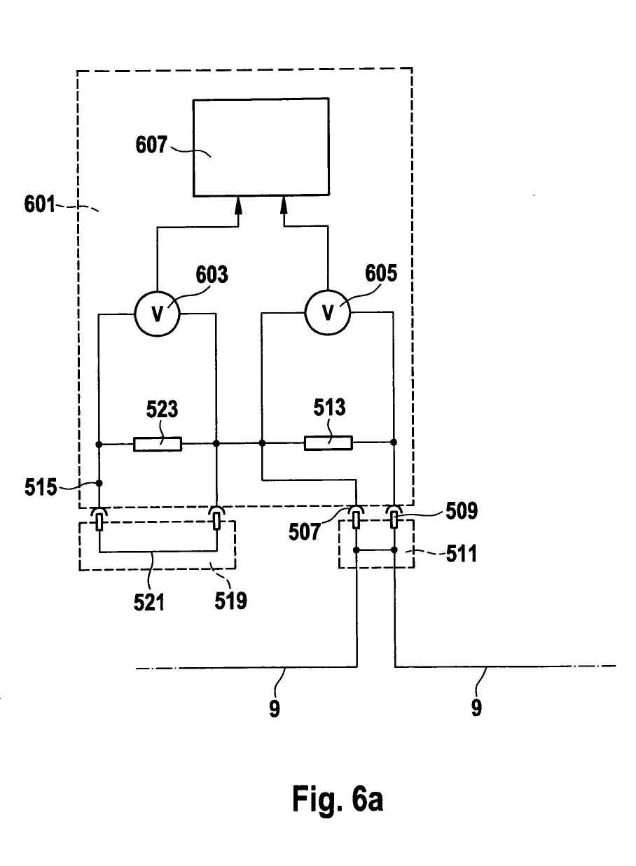

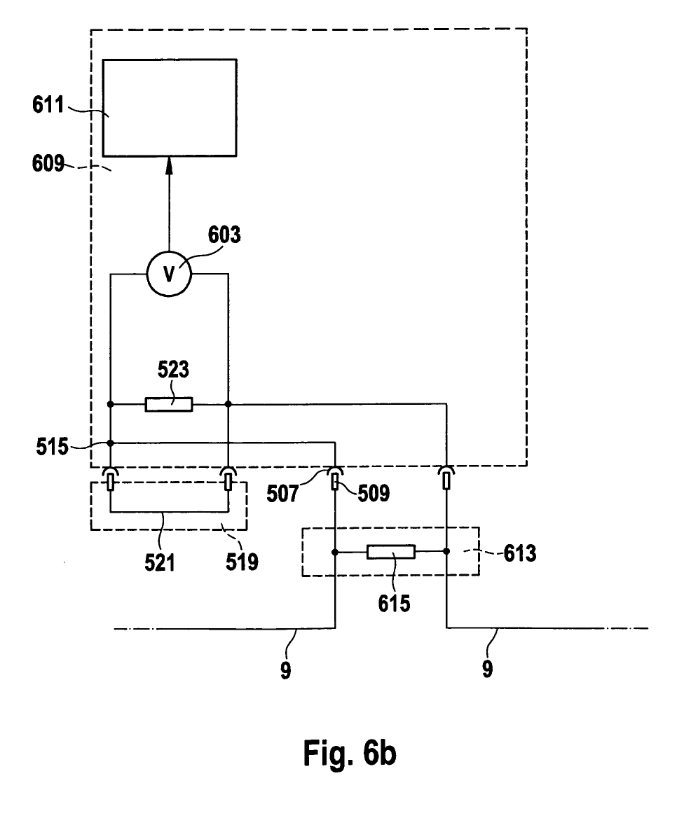

FIG. 6a shows a monitoring device 601, which has a first voltage measuring device 603 and a second voltage measuring device 605, in contrast with the exemplary embodiment shown in FIG. 5. First voltage measuring device 603 measures a voltage drop across resistor element 523. However, second voltage measuring device 605 measures a voltage drop across resistor element 513. One output of first voltage measuring device 603 and one output of second voltage measuring device 605 are connected to an evaluation unit 607. The connecting bridge shown in additional connection element 511 is also optional. On the basis of the measured voltages across resistor elements 523 and 513, evaluation unit 607 detects whether the monitoring device is connected to the power system or to the monitoring system in a fault-free manner.

In contrast with the exemplary embodiment shown in FIG. 6a, FIG. 6b shows a monitoring device 609 having only evaluation unit 611, which is provided for evaluation of the voltage across resistor 523. Furthermore, a contact point 613 having a resistor element 615 switchable between terminals 507 and 509 is also provided.

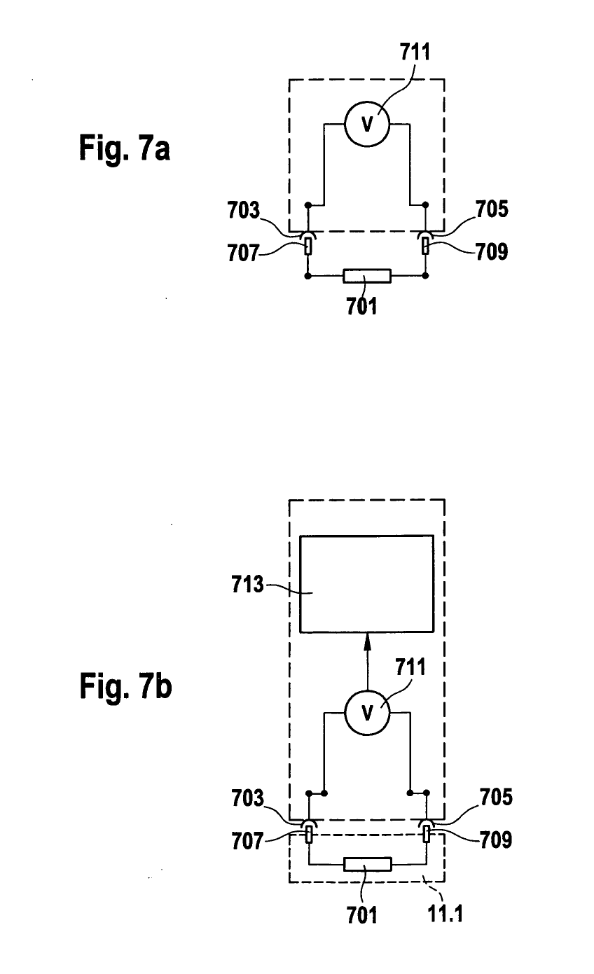

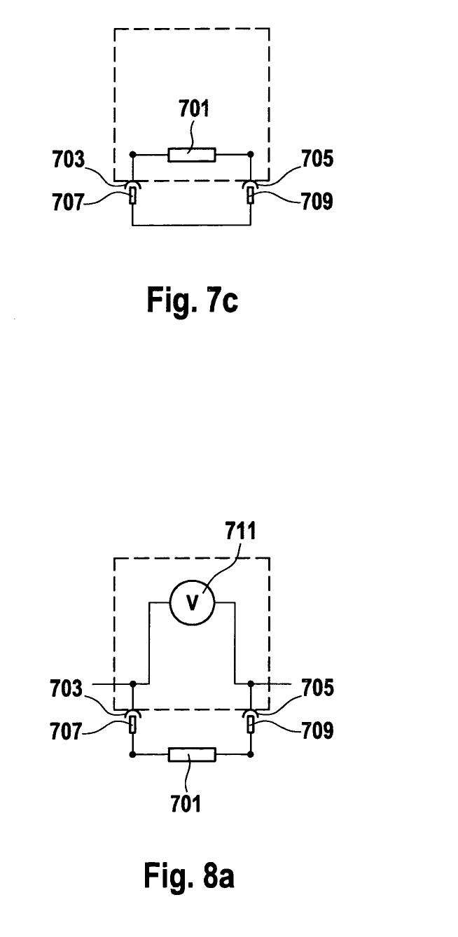

FIG. 7a shows a connection of a monitoring device to the monitoring system having a resistor element 701 as an exemplary embodiment. A first terminal 703 and a second terminal 705 of a connection element of the monitoring device are connected to a first terminal 707 and a second terminal 709 of another connection element of a monitoring system. Resistor element 701 may be situated in the additional connection element between terminals 707 and 709. In the event of a faulty connection, a current through resistor 701 is generated by a power source (not shown in FIG. 7), resulting in a voltage drop detectable by voltage measuring device 711. Voltage measuring device 711 directs a voltage measurement signal to an evaluation unit 713, which is shown in FIG. 7b and may perform a fault diagnosis on the basis of this signal.

FIG. 7b shows an alternative connection to the monitoring system and its pilot line, in which terminals 707 and 709 are short-circuited and in which resistor element 701 is situated between terminals 703 and 705.

As shown in FIG. 7c, the voltage measuring device and the evaluation unit may be omitted, so that only central power source unit 8 described above may detect the fault. Localization of the fault is possible only if impedances 701 in the components to be monitored are coded to permit unambiguous localization.

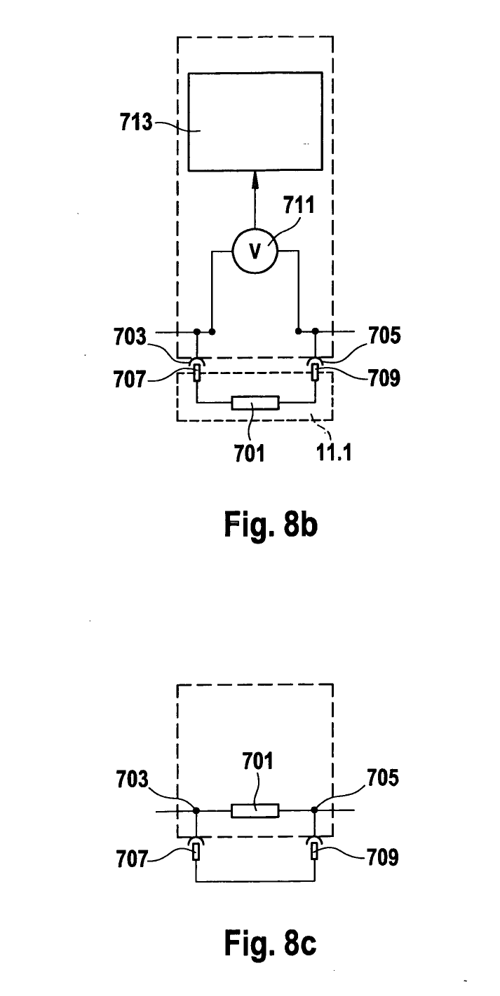

As shown in FIGS. 8a, 8b and 8c, the connection to the pilot line of the monitoring system may be accomplished by voltage measuring device 711 being switchable in series with the pilot line, as shown in FIGS. 8a and 8b. As FIG. 8c shows, the connection to the pilot line may also be accomplished via resistor element 701 assigned to the monitoring device.

As explained above, to create a pilot line, the components to be monitored and their connections, e.g., plug connectors or housing cover monitors, are connected to a separate line, which may correspond to pilot line 9. As shown in FIG. 2, pilot line 9 may be introduced into the components to be monitored via plug contacts 4.1.a, 4.n.b and 5.1.a, 5.n.a. These plug contacts may also optionally be designed as a single plug contact per component or may be integrated into an already existing signal plug.

Impedances 3.1, 3.n situated in the components to be monitored may be bridged with a low impedance via another plug connection, e.g., via plug connection 11.1, 11.n shown in FIG. 2, which may be implemented by lines 13.1, 13.n. Impedances 3.1, 3.n are expediently approximately of the same magnitude but may also be different. As shown in FIG. 2, a voltage measuring device 2.1, 2.n may be connected in parallel with impedances 3.1, 3.n, supplying their voltage signal to particular evaluation unit 6.1, 6.n. Power source 8 may be integrated into pilot line 9 and regulates the current in pilot line 9 at a constant value via control and evaluation unit 10, regardless of the number of terminal components to be monitored or monitoring devices in the pilot line.

If plug contact 11.1, 11.n. on one of components 1.1.a, 1.n.a to be monitored is separated or if a cover is opened, then the voltage drop across particular impedance 3.1, 3.n is greater than a defined threshold value. This voltage is measured via particular voltage measuring device 2.1, 2.n and processed in evaluation unit 6.1, 6.n. If the plug connection or the housing covers are closed and if the plug contacts of the pilot line are connected, then voltage measuring device 2.1, 2.n measures a voltage of approximately 0 V. For the current to remain constant in the case of a separated plug contact or an opened cover, power source 8 may set a higher voltage, which is detected by central evaluation unit 10, so it is discernible that a plug contact has been separated or a housing cover has been opened.

A separate plug contact or an open cover may additionally be detected decentrally by the component to be monitored. The component to be monitored may optionally initiate measures itself, as depicted in FIGS. 1 to 4. To do so, the terminal components to be monitored may mutually exchange their monitoring states, e.g., via the signal or bus connection 12, and may optionally perform a plausibility check of their monitoring states and/or report measures taken to the other components to be monitored and/or may send diagnostic information for locating the site of the error.

The plug contacts of pilot lines 4.1.b, 4.n.b and 5.1.b, 5.n.b may optionally be monitored with a parallel-connected impedance 513 in plug 511 in the same way as illustrated in FIG. 5, like the plug connectors of the low-voltage plug contacts or housing cover monitors 519.

If multiple contacts to be monitored are contained in one component, they may be wired in serial connection within the component. In this case, for decentralized diagnosis, each contact to be monitored may optionally be provided with a voltage measurement or multiple contacts may be provided with a single voltage measurement.

Reference impedance 701 from FIG. 7 may optionally also be integrated into the particular plug contact, e.g., into plug contact 11.1 from FIG. 2. However, only a single fault may thus be detected.

In addition, power source unit 7 shown in FIG. 2 may be integrated into one of components 1.1.a, 1.1.n to be monitored.

Furthermore, as shown in FIG. 5, a separate pilot contact plug 511 or 4.1, 4.n and 5.1, 5.n from FIG. 2 may be omitted if this plug is integratable into an already existing signal plug connection of monitoring component 1.1.a, 1.n.a from FIG. 2.

The evaluation devices may be supplied with power via a low-voltage vehicle power system having an operating voltage of 14 volts, for example. They also include a transmission device for emitting signals, each being assigned to a monitoring device or a terminal component, via bus link 12 shown in FIG. 2, for example. The transmission device may be designed to generate and transmit amplitude- and/or phase-modulated transmission signals, for example.

1-10. (canceled)

11. A monitoring device for monitoring a terminal of a terminal component on a power supply system, the terminal component being connectable to the power supply system and to a monitoring system via an electrical connection element, comprising:
a voltage measuring device to detect a voltage value of a voltage between a first terminal and a second terminal of the electrical connection element, the first terminal and the second terminal being connectable to the monitoring system; and
an evaluation unit to evaluate the voltage value, and to generate an indicating signal, which indicates a faulty terminal in the power supply system if the voltage value differs from a predetermined voltage value.

12. The monitoring device of claim 11, wherein a resistor element is switchable between the first terminal and the second terminal.

13. The monitoring device of claim 11, wherein the evaluation unit is configured to generate the indicating signal if the voltage value differs from the predetermined voltage value.

14. The monitoring device of claim 11, wherein the predetermined voltage value is between 0 volt and 1 volt.

15. The monitoring device of claim 11, wherein the voltage measuring device and the evaluation unit are situated in the connection element.

16. A terminal component, which includes one of a vehicle battery, a vehicle ignition coil, a vehicle control unit, a low-voltage vehicle battery system, a component housing, and a component housing cover, comprising:
a monitoring device for monitoring a terminal of a terminal component on a power supply system, the terminal component being connectable to the power supply system and to a monitoring system via an electrical connection element, including:
a voltage measuring device to detect a voltage value of a voltage between a first terminal and a second terminal of the electrical connection element, the first terminal and the second terminal being connectable to the monitoring system; and
an evaluation unit to evaluate the voltage value, and to generate an indicating signal, which indicates a faulty terminal in the power supply system if the voltage value differs from a predetermined voltage value.

17. A monitoring system for monitoring a terminal of at least one terminal component in a power supply system, the terminal component being connectable to the power supply system and to a monitoring system via an electrical connection element, comprising:
a monitoring device for monitoring a terminal of a terminal component on a power supply system, the terminal component being connectable to the power supply system and to a monitoring system via an electrical connection element, including:
a voltage measuring device to detect a voltage value of a voltage between a first terminal and a second terminal of the electrical connection element, the first terminal and the second terminal being connectable to the monitoring system; and
an evaluation unit to evaluate the voltage value, and to generate an indicating signal, which indicates a faulty terminal in the power supply system if the voltage value differs from a predetermined voltage value; and
a power generating device, which is a power source for supplying an electric current of a predetermined amplitude to the first terminal of the connection element, to produce a voltage drop between the first terminal and the second terminal.

18. The monitoring system of claim 17, further comprising:
an additional connection element to which the connection element of the terminal component is connectable, wherein the additional connection element has one of a low-impedance connection and a resistor element between a first terminal of the additional connection element and the second terminal of the other connection element, and wherein the terminals of the additional connection element are connectable to the terminals of the connection element.

19. The monitoring system of claim 17, further comprising:
a central evaluation unit connectable to the evaluation unit of the monitoring device to receive the indicating signal and, in the event of a connection error, to output an error signal indicating the terminal component.

20. A vehicle power system, comprising:
a monitoring device for monitoring a terminal of a terminal component on a power supply system, the terminal component being connectable to the power supply system and to a monitoring system via an electrical connection element, including:
a voltage measuring device to detect a voltage value of a voltage between a first terminal and a second terminal of the electrical connection element, the first terminal and the second terminal being connectable to the monitoring system; and
an evaluation unit to evaluate the voltage value, and to generate an indicating signal, which indicates a faulty terminal in the power supply system if the voltage value differs from a predetermined voltage value; and
a monitoring system for monitoring a terminal of at least one terminal component in a power supply system, the terminal component being connectable to the power supply system and to a monitoring system via an electrical connection element, including:
another monitoring device for monitoring a terminal of a terminal component on a power supply system, the terminal component being connectable to the power supply system and to a monitoring system via an electrical connection element, including:
another voltage measuring device to detect a voltage value of a voltage between a first terminal and a second terminal of the electrical connection element, the first terminal and the second terminal being connectable to the monitoring system; and
another evaluation unit to evaluate the voltage value, and to generate an indicating signal, which indicates a faulty terminal in the power supply system if the voltage value differs from a predetermined voltage value; and
a power generating device, which is a power source for supplying an electric current of a predetermined amplitude to the first terminal of the connection element, to produce a voltage drop between the first terminal and the second terminal.
